(19) United States
(12) Patent Application Publication
(10) Pub. No.: US 2007/0003785 A1
(43) Pub. Date: Jan. 4, 2007

(54) Electroluminescent devices containing benzidine derivatives

(75) Inventors: Wojciech K. Slusarek, Rochester, NY (US); Michele L. Ricks, Rochester, NY (US); Marcel B. Madaras, Webster, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/172,024

(22) Filed: Jun. 30, 2005

(51) Int. Cl. H01L 51/54; H05B 33/12

(52) U.S. Cl. 428/690; 428/917; 428/212; 313/504; 313/506; 313/112; 257/E51.051; 257/98

(57) ABSTRACT

An organic light-emitting diode device (OLED) comprises a cathode, a light-emitting layer, and an anode in that order, in which there is located a first layer (L1) adjacent to the light-emitting layer on the anode side and a second layer (L2) adjacent to L1 on the anode side, in which:

(a) layer L1 comprises a benzidine derivative (B1) having an oxidation potential of 0.8-0.9 V; and

(b) layer L2 comprises a benzidine derivative (B2) having an oxidation potential greater than 0.7 V and exhibiting a glass transition temperature, Tg, of greater than 125° C.

### CROSS-REFERENCE TO RELATED APPLICATION

Reference is made to commonly assigned U.S. Ser. No. 10/810,282 by Richard L. Parton, et al., filed on Mar. 26, 2004, entitled “Organic Element For Electroluminescent Devices.

### FIELD OF THE INVENTION

This invention relates to organic electroluminescent devices. More specifically, this invention relates to devices that emit light from a current-conducting organic layer and have good high-temperature stability.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, 30, 322, (1969); and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g. <1.0 μm) between the anode and the cathode. Herein, the term “organic EL element” encompasses the layers between the anode and cathode. Reducing the thickness lowered the resistance of the organic layers and has enabled devices that operate at much lower voltage. In a basic two-layer EL device structure, described first in U.S. Pat. No. 4,356,429, one organic layer of the EL element adjacent to the anode is specifically chosen to transport holes, and therefore is referred to as the hole-transporting layer, and the other organic layer is specifically chosen to transport electrons and is referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by C. Tang et al. (J. Applied Physics, Vol. 65, 3610 (1989)). The light-emitting layer commonly consists of a host material doped with a guest material, otherwise known as a dopant. Still further, there has been proposed in U.S. Pat. No. 4,769,292 a four-layer EL element comprising a hole injecting layer (HIL), a hole-transporting layer (HTL), a light-emitting layer (LEL) and an electron-transporting/injecting layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others.

While not always necessary, it is often useful to include a hole-transporting layer in an OLED device. The hole-transporting layer of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more desirable class of aromatic tertiary amines include at least two aromatic tertiary amine moieties as described in U.S. Pat. No. 4,720,432 and U.S. Pat. No. 5,061,569, U.S. Pat. No. 5,061,569, U.S. Pat. No. 6,074,734, and U.S. Pat. No. 6,242,115, US 2004/0023060, US 2003/0186077, US 2004/0170863, JP 2004/339134. The use of tertiary amines such as tetrarylbenzidine derivatives as hole-transporting materials is well-known.

However, many of these tertiary amines, when used as hole-transporting materials, afford devices with operating lifetimes that are not as long as desired. In particular, it is sometimes desirable to operate the devices under high temperature conditions, for example, for automotive applications. In these cases, it has been especially difficult to find suitable hole-transporting materials that afford good operating lifetimes at high temperatures.

EP 924192A1B1, US 5759444, US 20020168543, JP 11176574A, JP 11185965A, JP 1 1219787A, JP 11273860A, T. Selby and S. Blackstock, J. Am. Chem. Soc., 121, 7152 (1999), and Y. Qiu, J. Qiao, Y. Gao, D. Zhang, L. Wang, Syn. Met., 129, 25 (2002) suggest the use of tetraryl substituted naphthyldiamine derivatives in EL elements generally. Many of these materials contain 1,4-diamines, which can cause the materials to have low oxidation potentials and in some cases to be thermally unstable.

U.S. Pat. No. 6,849,345 and U.S. Ser. No. 10/810,282, filed on Mar. 26, 2004 and references cited therein, describe tetraryl-substituted naphthylamine hole-transporting materials in an OLED device. They also describe the use of sequential layers of tetraryl-substituted naphthylamine and of tetraryl-substituted benzidine hole-transporting materials. However, tetraryl-substituted naphthylamines, or the combination layers described, often do not afford sufficient operational stability, particularly at high temperatures.

Many hole-transporting materials have been described that have a high glass transition temperature (Tg), for example see JP 2004/339134 and US 2004/0170863 ever, although the Tg value is important, simply having a high Tg is insufficient to provide good high-temperature stability.

Thus there remains a need for organic EL device components that will provide improved operating lifetimes, especially at higher temperatures.

### SUMMARY OF THE INVENTION

The invention provides an organic light-emitting diode device (OLED) comprising a cathode, a light-emitting layer, and an anode in that order, in which there is located a first layer (L1) adjacent to the light-emitting layer on the anode side and a second layer (L2) adjacent to L1 on the anode side, in which:

(a) layer L1 comprises a benzidine derivative (B1) having an oxidation potential of 0.8-0.9 V; and

(b) layer L2 comprises a benzidine derivative (B2) having an oxidation potential greater than 0.7 V and exhibiting a glass transition temperature, Tg, of greater than 125° C.

Such a device provides improved operating lifetimes, especially at higher temperatures.

### BRIEF DESCRIPTION OF THE DRAWINGS

The Figure shows a schematic cross-sectional view of one embodiment of the present invention including a light-emitting layer (109), layer L1 (107) and layer L2 (106), and an optional hole-injecting layer (HIL, 105).

### DETAILED DESCRIPTION OF THE INVENTION

As previously described, the OLED device of the invention includes a cathode, a light-emitting layer, and an anode in which there is located a first layer (L1) adjacent to the light-emitting layer on the anode side and a second layer (L2), adjacent to the first layer and on the anode side. Desirably, the materials comprising L1 and L2 facilitate the transportation of holes through the device. The OLED device may have additional layers, such as, for example a hole-injecting layer or an electron-injecting layer.

The L1 layer includes a benzidine derivative (B1) having an oxidation potential of 0.8-0.9 V vs. SCE. A benzidine compound of the invention consists of a biphenyl moiety, formed by linking two benzene groups, that are substituted in the 4,4′ positions with N,N,N′,N′-tetra-aromatic amino groups.

Oxidation potentials can be measured by well-known literature procedures, such as cyclic voltammetry (CV) and Osteryoung square-wave voltammtry (SWV). For a review of electrochemical measurements, see J. O. Bockris and A. K. N. Reddy, Modern Electrochemistiy, Plenum Press, New York; and A. J. Bard and L. R. Faulkner, Electrochemical Methods, John Wiley & Sons, New York, and references cited therein. Oxidation potentials are always reported versus a reference. In our case, the reference is the saturated calomel electrode (SCE).

In one embodiment, the benzidine derivative (B1) is represented by Formula (1).

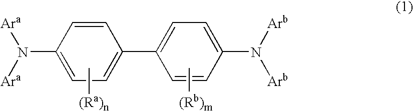

In Formula (1), each Ar^{a} and each Ar^{b} may be the same or different, and each represents an independently selected aromatic group, such as a phenyl group, a 4-tolyl group, a 3-tolyl group, a 1-naphthyl group, or a 2-naphthyl group. In one suitable embodiment, at least one Ar^{a} represents a phenyl group and at least one Ar^{a} represents a naphthyl group. In another desirable embodiment, one Ar^{a} and one Ar^{b} each represent an independently selected a phenyl group and one Ar^{a} and one Ar^{b} each represent an independently selected a naphthyl group. Two Ar^{a} groups and two Ar^{b} groups may, independently, join together to form additional rings. Each R^{a} and each R^{b} may be the same or different and each represents an independently selected substituent group such as, for example, a methyl group or fluoro group. In Formula (1), n and m are 0-4. In one desirable embodiment, n and m are both 0.

Each Ar^{a}, Ar^{b}, R^{a}, and R^{b}, as well as n and m, are chosen so that the oxidation potential of B1 is 0.8-0.9 V vs. SCE. In one suitable embodiment, the 5 oxidation potential of B1 is 0.85-0.9 V vs. SCE. Illustrative examples of B1 include those listed below.
HTM-1 N,N,N′,N′-Tetra-p-tolyl-4-4′-diaminobiphenyl
HTM-2 N,N,N′,N′-Tetraphenyl-4,4′-diaminobiphenyl
HTM-3 4,4′-Bis[N-(1-naphthyl)-N-phenylamino]biphenyl (NPB)
HTM-4 4,4′-Bis[N-(2-naphthyl)-N-phenylamino]biphenyl
HTM-5 4,4′-Bis[N-(3-acenaphthenyl)-N-phenylamino]biphenyl
HTM-6 4,4′-Bis[N-(9-anthryl)-N-phenylamino]biphenyl
HTM-7 4,4″-Bis[N-(1-anthryl)-N-phenylamino]-p-terphenyl
HTM-8 4,4′-Bis[N-(2-phenanthryl)-N-phenylamino]biphenyl
HTM-9 4,4′-Bis[N-(8-fluoranthenyl)-N-phenylamino]biphenyl
HTM-10 4,4′-Bis[N-(2-pyrenyl)-N-phenylamino]biphenyl
HTM-11 4,4′-Bis[N-(2-naphthacenyl)-N-phenylamino]biphenyl
HTM-12 4,4′-Bis[N-(2-perylenyl)-N-phenylamino]biphenyl
HTM-13 4,4′-Bis[N-(1-coronenyl)-N-phenylamino]biphenyl
HTM-14 4,4′-Bis{N-phenyl-N-[4-(1-naphthyl)-phenyl]amino}biphenyl
HTM-15 4,440 -Bis[N-phenyl-N-(2-pyrenyl)amino]biphenyl
HTM-16 4,4′-Bis[N-(3-methylphenyl)-N-phenylamino]biphenyl (TPD).

Layer L2 includes a benzidine derivative (B2) having an oxidation potential greater than 0.7 V. In one embodiment, the oxidation potential of B2 is greater than 0.75 V or even greater than 0.80 V. In one aspect of the invention, the oxidation potential of B2 is less than B1. Suitably, the difference in oxidation potential between B1 and B2 is in the range of 0.1 V to 0.005 V or even in the range of 0.05 V to 0.005 V.

B2 exhibits a glass transition temperature (Tg) of greater than 125° C. Tg values can be determined by methods described in the literature. For a review of glass transition temperatures and methods of measurement, see S. L. Rosen, Fundamental Principles of Poymeric Materials, John Wiley & Sons, New York (1982). In one aspect of the invention, B2 has a Tg greater than 130° C., 135° C., 140° C., 150° C., 165° C. or even greater than 170° C. Desirably, the Tg of B13 is greater than 90° C.

In one desirable embodiment, B2 is represented by Formula (2).

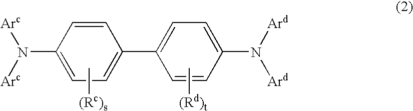

In Formula (2), each Ar^{c} and each Ar^{d} may be the same or different and each represents an independently selected aromatic group such as a phenyl group, a 4-tolyl group, a 3-tolyl group, a 1-naphthyl group, or a 2-naphthyl group. Two Ar^{c} groups and two Ar^{d} groups may, independently, join together to form additional rings. In one suitable embodiment, each Ar^{c} and each Ar^{d} represents an independently selected naphthyl group.

In still another embodiment, at least one Ar^{c} or Ar^{d} represents a group of Formula (2a). Suitably, in one embodiment, at least one Ar^{c} and at least one Ar^{d} represents an independently selected group of Formula (2a).

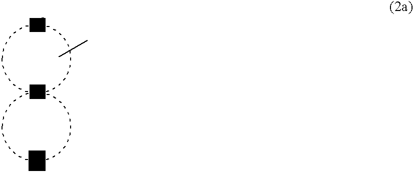

In Formula (2a), Z^{a} and Z^{b} independently represent the atoms necessary to form a five- or six-membered ring group. The line segment drawn to the center of the ring denotes that bonding to B2 can occur at any atom in that ring. Desirably, at least one ring group includes at least one fused aromatic ring. In another suitable embodiment, both Z^{a} and Z^{b} represent the atoms necessary to form an independently selected five-membered ring group.

In a further embodiment, at least one Ar^{c} or Ar^{d} represents a substituent group of Formula (2b).

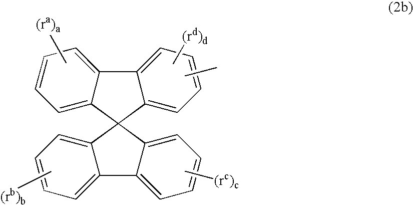

In Formula (2b), each r^{a}, r^{b}, r^{c}, and r^{d} represents an independently selected substituent, such as a methyl group, a phenyl group, or a trifluoromethyl group. Adjacent r^{a}, r^{b}, r^{c}, and r^{d} groups may combine to form fused rings. In Formula (2b), a, b, and c are independently 0-4 and d is 0-3.

Illustrative examples of substituents of Formula (2a) and (2b) are shown below.

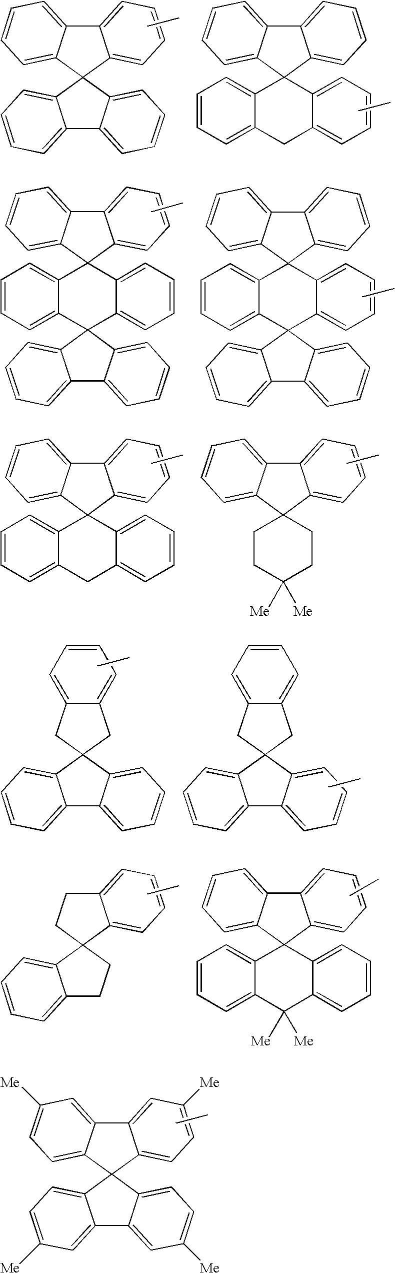

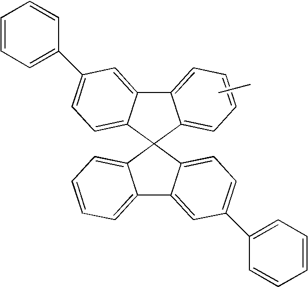

In Formula (2), Each R^{c} and each R^{d} may be the same or different and each represents an independently selected substituent group such as a methyl group or fluoro group. In one alternative embodiment, at least one R^{c} and at least one R^{d} join together to form a ring. Illustrative examples are shown below.

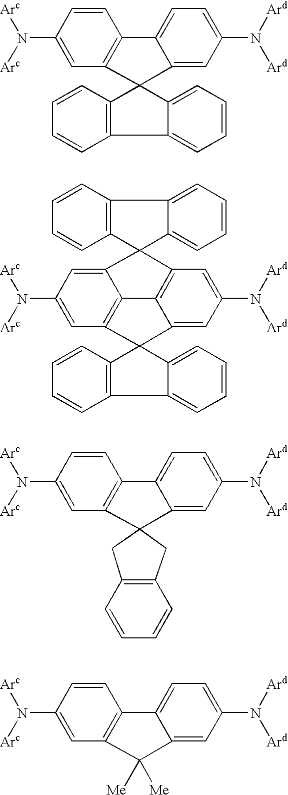

In Formula (2), s and t are independently 0-4. In one aspect of the invention, s and t are both 0. In one suitable embodiment, Formula (2) includes at least 10, 12 or even 14 or more rings

Illustrative examples of compounds of Formula (2) useful in the present invention are listed below.

| | |
|---|---|
| Cpd-1 | 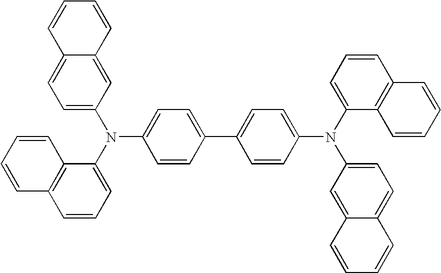 |
| Cpd-2 | 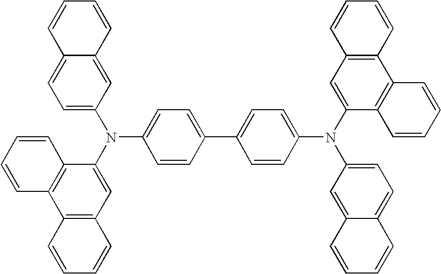 |
| Cpd-3 | 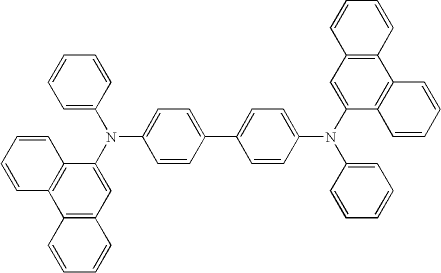 |
| | 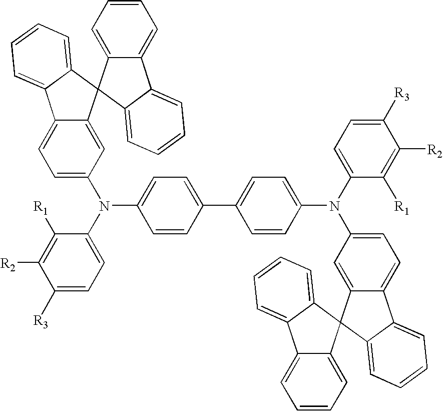 |

| | R₁ | R₂ | R₃ |
|---|---|---|---|
| Cpd-4 | H | H | MeO |
| Cpd-5 | H | H | Me |
| Cpd-6 | H | H | H |
| Cpd-7 | H | H | CF₃ |
| Cpd-8 | H | Me | H |
| Cpd-9 | H | H | Ph |
| Cpd-10 | Me | Me | H |

| | |
|---|---|
| Cpd-11 | 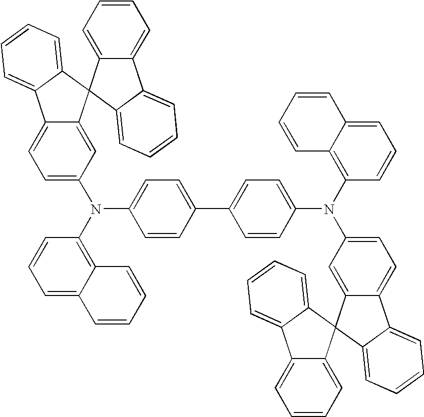 |
| Cpd-12 | 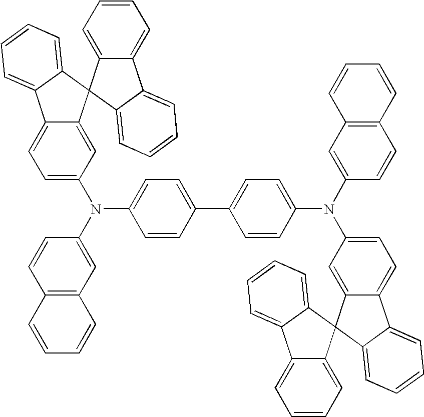 |
| Cpd-13 | 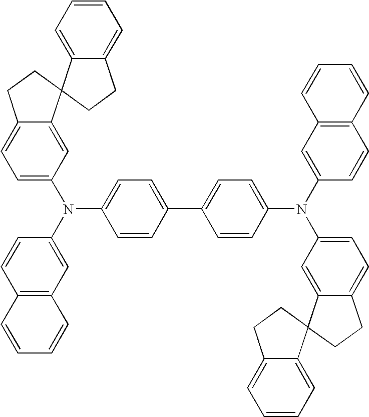 |
| Cpd-14 | 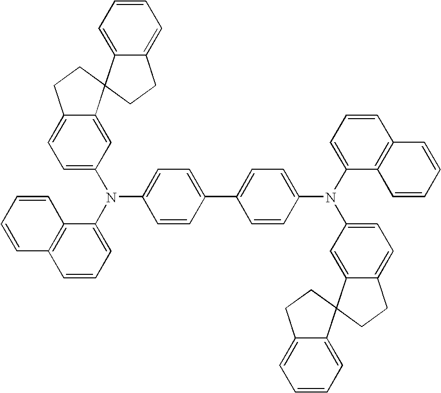 |
| Cpd-15 | 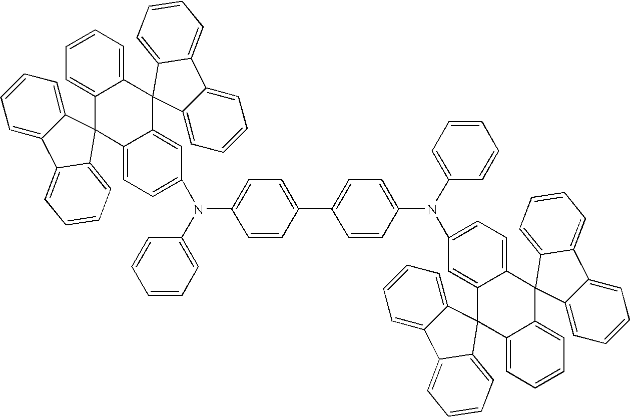 |
| Cpd-16 | 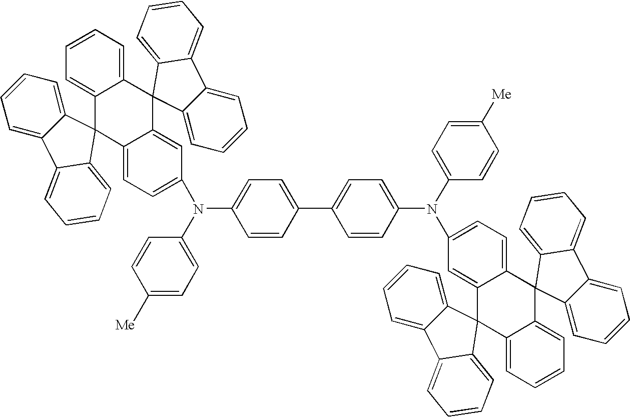 |
| Cpd-17 | 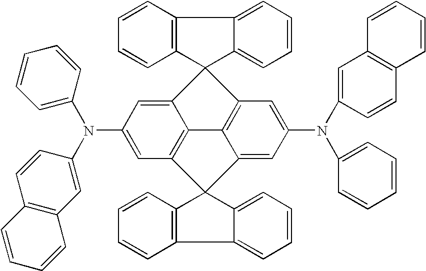 |
| Cpd-18 | 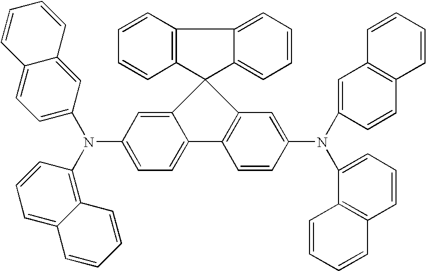 |
| Cpd-19 | 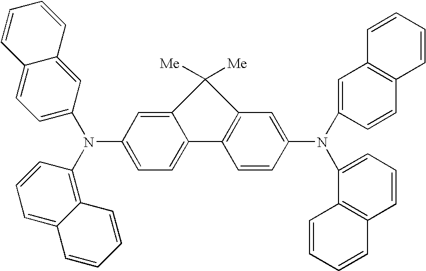 |
| Cpd-20 | 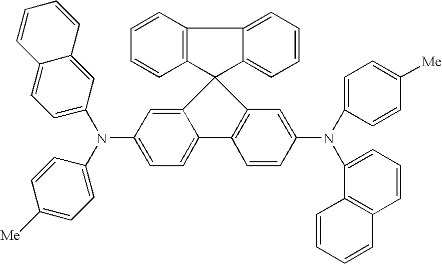 |
| Cpd-21 | 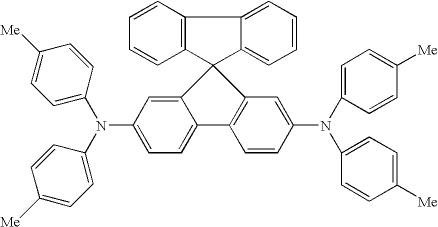 |
| Cpd-22 | 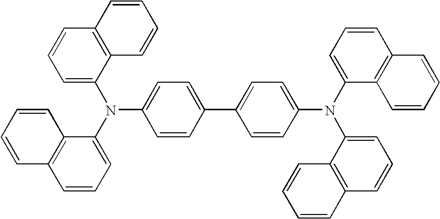 |
| Cpd-23 | 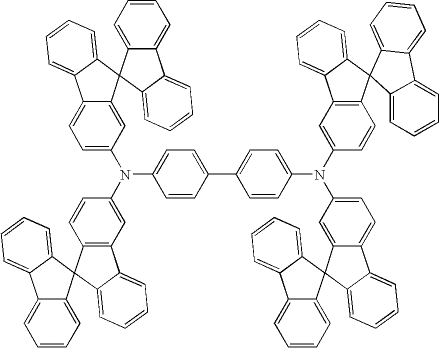 |
| Cpd-24 | 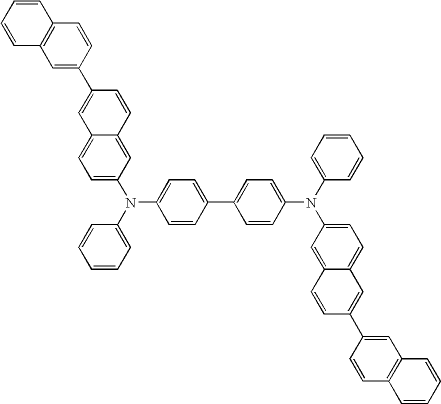 |

In one aspect of the invention, the structure of B1 includes at least 8 rings and the structure of B2 includes at least 10, 12 or even 14 rings.

In another aspect, B1 is 4,4′-Bis[N-(2-naphthyl)-N-phenylamino]-1,1 ′-biphenyl. B2 is 4,4′-Bis[N-(2-naphthyl)-N-(1-naphthyl)amino]-1,1′-biphenyl or B2 is a 9,9′-spirobifluorene derivative.

Benzidine derivatives such as those represented by Formula (1) and Formula (2), can be prepared by methods know in the literature. For example, see U.S. Pat. No. 5,929,281 and US 2004/0023060 and references cited therein.

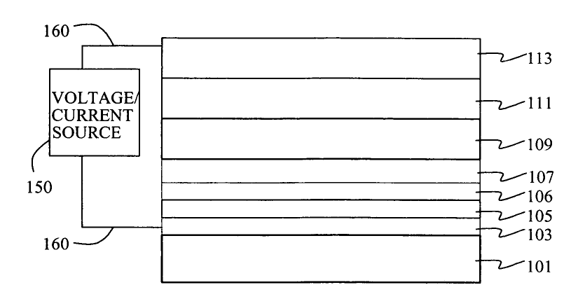

In still a further aspect of the invention, it may desirable to include a light-emitting material in layer L1. Suitably, the light-emitting material is a fluorescent dopant. For example, it may be desirable to include a yellow-light emitting material in layer L1 (FIG. 1, layer 107) and a blue light-emitting material in the LEL layer (FIG. 1, layer 109) in order to fabricate a device that emits white light.

Examples of useful yellow dopants include 5,6,11,12-tetraphenylnaphthacene (rubrene); 6,11-diphenyl-5,12-bis(4-(6-methyl-benzothiazol-2-yl)phenyl)naphthacene; 5,6,11,1 2-tetra(2-naphthyl)naphthacene; and

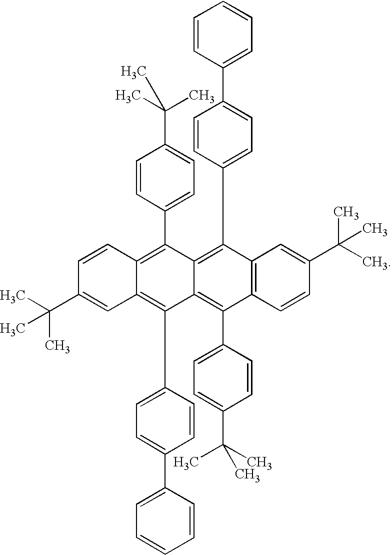

Examples of yellow light-emitting materials also include compounds represented by the following formula:

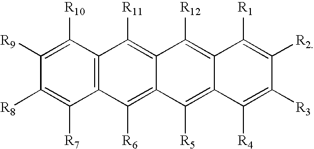

R₁, R₂, R₃, R₄, R₅, R₆, R₇, R₈, R₉, R₁₀, R₁₁, and R₁₂ are independently selected as hydrogen or substituent groups. Such substituent groups may join to form further fused rings. In one suitable embodiment, R₁, R₃, R₄, R₇, R₉, R₁₀, represent hydrogen; R₂ and R₈ represent hydrogen or independently selected alkyl groups; R₅, R₆, R₁₁, and R₁₂ represent independently selected aryl groups.

Many fluorescent materials that emit blue light are known in the art. Particularly useful classes of blue emitters include perylene and its derivatives such as a perylene nucleus bearing one or more substituents such as an alkyl group or an aryl group. A desirable perylene derivative for use as a blue emitting material is 2,5,8,11-tetra-t-butylperylene.

Another useful class of fluorescent materials includes blue-light emitting derivatives of distyrylarenes such as distyrylbenzene and distyrylbiphenyl, including compounds described in U.S. Pat. No. 5,121,029. Among derivatives of distyrylarenes that provide blue luminescence, particularly useful are those substituted with diarylamino groups, also known as distyrylamines. Illustrative examples include those listed below.

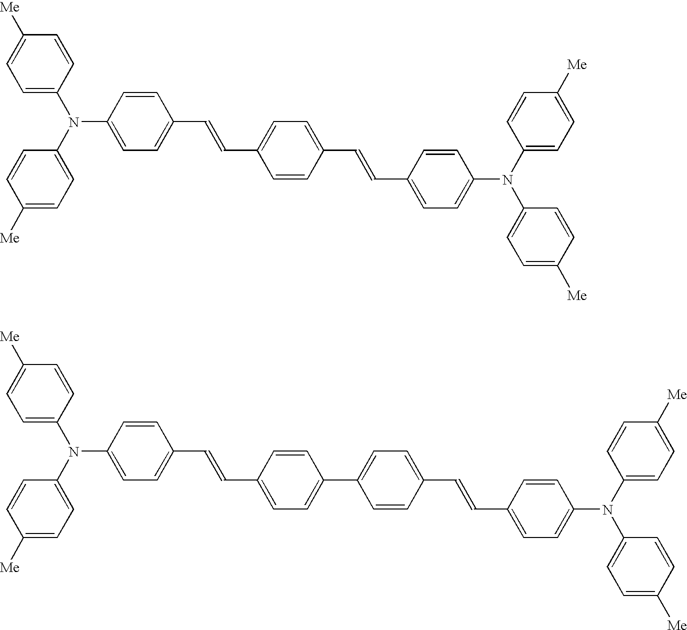

Another useful class of blue emitters comprises a boron atom, such as those described in US 2003/0201415. Illustrative examples of useful boron-containing blue fluorescent materials are listed below.

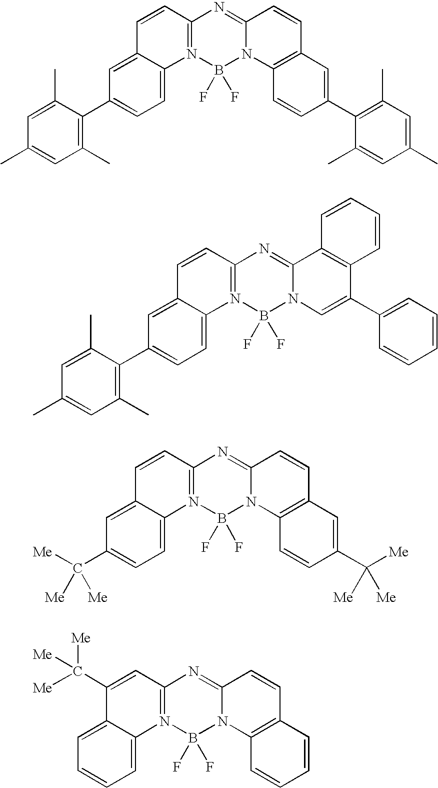

The thickness of layers L1 and L2 are independent of each other and often between 1 and about 100 nm, suitably between 2 and 50 nm, and desirably between 5 and 25 nm.

As previously described, layers L1 and L2 may independently contain additional materials, such as light-emitting materials. In one embodiment, one or both of the layers contain one or more additional hole-transporting materials. In one embodiment, layer L1 includes at least 50%, 60%, 75%, or 90% or more of B1. In another embodiment, layer L2 includes at least 50%, 60%, 75%, or 90% or more of B2.

Unless otherwise specifically stated, use of the term “substituted” or “substituent” means any group or atom other than hydrogen. Unless otherwise provided, when a group, compound or formula containing a substitutable hydrogen is referred to, it is also intended to encompass not only the unsubstituted form, but also form further substituted with any substituent group or groups as herein mentioned, so long as the substituent does not destroy properties necessary for utility. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

General Device Architecture

The present invention can be employed in many EL device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

A typical structure according to the present invention and especially useful for a small molecule device, is shown in FIG. 1 and is comprised of a substrate 101, an anode 103, a hole-injecting layer 105, a hole-transporting layer 107, a light-emitting layer 109, an electron-transporting layer 111, and a cathode 113. These layers are described in detail below. Note that the substrate 101 may alternatively be located adjacent to the cathode 113, or the substrate 101 may actually constitute the anode 103 or cathode 113. The organic layers between the anode 103 and cathode 113 are conveniently referred to as the organic EL element. Also, the total combined thickness of the organic layers is desirably less than 500 nm. If the device includes phosphorescent material, a hole-blocking layer, located between the light-emitting layer and the electron-transporting layer, may be present.

The anode 103 and cathode 113 of the OLED are connected to a voltage/current source 150 through electrical conductors 160. The OLED is operated by applying a potential between the anode 103 and cathode 113 such that the anode 103 is at a more positive potential than the cathode 113. Holes are injected into the organic EL element from the anode 103 and electrons are injected into the organic EL element at the cathode 113. Enhanced device stability can sometimes be achieved when the OLED is operated in an AC mode where, for some time period in the AC cycle, the potential bias is reversed and no current flows. An example of an AC driven OLED is described in U.S. Pat. No. 5,552,678.

Substrate

The OLED device of this invention is typically provided over a supporting substrate 101 where either the cathode 113 or anode 103 can be in contact with the substrate. The electrode in contact with the substrate 101 is conveniently referred to as the bottom electrode. Conventionally, the bottom electrode is the anode 103, but this invention is not limited to that configuration. The substrate 101 can either be light transmissive or opaque, depending on the intended direction of light emission. The light transmissive property is desirable for viewing the EL emission through the substrate 101. Transparent glass or plastic is commonly employed in such cases. The substrate 101 can be a complex structure comprising multiple layers of materials. This is typically the case for active matrix substrates wherein TFTs are provided below the OLED layers. It is still necessary that the substrate 101, at least in the emissive pixelated areas, be comprised of largely transparent materials such as glass or polymers. For applications where the EL emission is viewed through the top electrode, the transmissive characteristic of the bottom support is immaterial, and therefore the substrate can be light transmissive, light absorbing or light reflective. Substrates for use in this case include, but are not limited to, glass, plastic, semiconductor materials such as silicon, ceramics, and circuit board materials. Again, the substrate 101 can be a complex structure comprising multiple layers of materials such as found in active matrix TFT designs. It is necessary to provide in these device configurations a light-transparent top electrode.

Anode

When the desired electroluminescent light emission (EL) is viewed through the anode, the anode 103 should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode 103. For applications where EL emission is viewed only through the cathode 113, the transmissive characteristics of the anode 103 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize short circuits or enhance reflectivity.

Cathode

When light emission is viewed solely through the anode 103, the cathode 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)), the cathode being capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of A1 as described in U.S. Pat. No. 5,677,572. An ETL material doped with an alkali metal, for example, Li-doped Alq, is another example of a useful EIL. Other useful cathode material sets include, but are not limited to, those disclosed in U.S. Pat. Nos. 5,059,861, 5,059,862, and 6,140,763.

When light emission is viewed through the cathode, the cathode 113 must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Hole-Injecting Layer (HIL)

A hole-injecting layer 105 may be provided between anode 103 and hole-transporting layer 107. The hole-injecting layer can serve to improve the film formation property of subsequent organic layers and to facilitate injection of holes into the hole-transporting layer 107. Suitable materials for use in the hole-injecting layer 105 include, but are not limited to, porphyrinic compounds as described in U.S. Pat. No. 4,720,432, plasma-deposited fluorocarbon polymers as described in U.S. Pat. No. 6,208,075, and some aromatic amines, for example, MTDATA (4,4′,4″-tris[(3-methylphenyl)phenylamino]triphenylamine). Alternative hole-injecting materials reportedly useful in organic EL devices are described in EP 0 891121 A1 and EP 1 029 909 A1. A hole-injection layer is conveniently used in the present invention, and is desirably a plasma-deposited fluorocarbon polymer. The thickness of a hole-injection layer containing a plasma-deposited fluorocarbon polymer can be in the range of 0.2 nm to 15 nm and suitably in the range of 0.3 to 1.5 nm.

Hole-Transporting Layer (HTL)

Layers 106 and 107 have already been described. Desirably these layers have good hole-transporting properties. However additional layers of hole-transporting materials, such as aromatic tertiary amine materials may be present in some embodiments. An aromatic tertiary amine is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520 and in Kawamura et al. U.S. Pat. No. 6,074,734.

A more preferred class of aromatic tertiary amines is those which include at least two aromatic tertiary amine moieties as described in U.S. Pat. No. 4,720,432 and U.S. Pat. No. 5,061,569. Such compounds include those represented by structural formula (A). 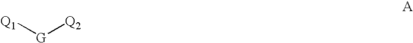
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B): 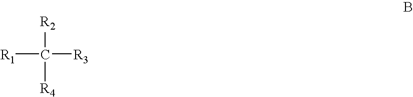
where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C): 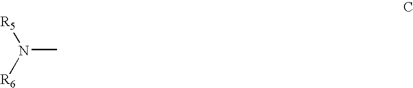
wherein R₅ and R₆ are independently selected aryl groups. In one embodiment, at least one of R₅ or R₆ contains a polycyclic fused ring structure, e.g., a naphthalene.

Another class of aromatic tertiary amines is the tetraaryldiamines. Desirable tetraaryldiamines include two diarylamino groups, such as indicated by formula (C), linked through an arylene group. Useful tetraaryldiamines include those represented by formula (D). 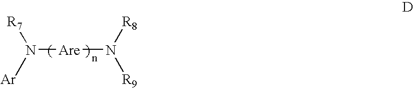
wherein

each Are is an independently selected arylene group, such as a phenylene or anthracene moiety,

n is an integer of from 1 to 4, and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and halide such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single tertiary amine compound or a mixture of such compounds. Specifically, one may employ a triarylamine, such as a triarylamine satisfying the formula (B), in combination with a tetraaryldiamine, such as indicated by formula (D). Illustrative of useful aromatic tertiary amines are the following:

1,1-Bis(4-di-p-tolylaminophenyl)cyclohexane (TAPC)

1,1-Bis(4-di-p-tolylaminophenyl)-4-methylcyclohexane

1,1-Bis(4-di-p-tolylaminophenyl)-4-phenylcyclohexane

1,1-Bis(4-di-p-tolylaminophenyl)-3-phenylpropane (TAPPP)

N,N,N′,N′-tetraphenyl-4,4′″-diamino-1,1′:4′,1″:4″,1′″-quaterphenyl

Bis(4-dimethylamino-2-methylphenyl)phenylmethane

1,4-bis[2-[4-[N,N-di(p-toly)amino]phenyl]vinyl]benzene (BDTAPVB)

N,N,N′,N′-Tetra-p-tolyl-4,4′-diaminobiphenyl (TTB)

N,N,N′,N′-Tetraphenyl-4,4′-diaminobiphenyl

N,N,N′,N′-tetra-1-naphthyl-4,4′-diaminobiphenyl

N,N,N′,N′-tetra-2-naphthyl-4,4′-diaminobiphenyl

N-Phenylcarbazole

4,4′-Bis[N-(1-naphthyl)-N-phenylamino]biphenyl (NPB)

4,4′-Bis[N-(1-naphthyl)-N-(2-naphthyl)amino]biphenyl (TNB)

4,4′-Bis[N-(1-naphthyl)-N-phenylamino]p-terphenyl

4,4′-Bis[N-(2-naphthyl)-N-phenylamino]biphenyl

4,4′-Bis[N-(3-acenaphthenyl)-N-phenylamino]biphenyl

1,5-Bis[N-(1-naphthyl)-N-phenylamino]naphthalene

4,4′-Bis[N-(9-anthryl)-N-phenylamino]biphenyl

4,4′-Bis[N-(1-anthryl)-N-phenylamino]-p-terphenyl

4,4′-Bis[N-(2-phenanthryl)-N-phenylamino]biphenyl

4,4′-Bis[N-(8-fluoranthenyl)-N-phenylamino]biphenyl

4,4′-Bis[N-(2-pyrenyl)-N-phenylamino]biphenyl

4,4′-Bis[N-(2-naphthacenyl)-N-phenylamino]biphenyl

4,4′-Bis[N-(2-perylenyl)-N-phenylamino]biphenyl

4,4′-Bis[N-(1-coronenyl)-N-phenylamino]biphenyl

2,6-Bis(di-p-tolylamino)naphthalene

2,6-Bis[di-(1-naphthyl)amino]naphthalene

2,6-Bis[N-(1-naphthyl)-N-(2-naphthyl)amino]naphthalene

N,N,N′,N′-Tetra(2-naphthyl)-4,4″-diamino-p-terphenyl

4,4′-Bis{N-phenyl-N-[4-(1-naphthyl)-phenyl]amino}biphenyl

2,6-Bis[N,N-di(2-naphthyl)amino]fluorene

4,4′,4″-tris[(3-methylphenyl)phenylamino]triphenylamine (MTDATA)

4,4′-Bis[N-(3-methylphenyl)-N-phenylamino]biphenyl (TPD)

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS. It is also possible for the hole-transporting layer to comprise two or more sublayers of differing compositions, the composition of each sublayer being as described above. The thickness of the hole-transporting layer can be between 10 and about 500 nm and suitably between 50 and 300 nm.

Light-Emitting Layer (LEL)

As more fully described in U.S. Pat. Nos. 4,769,292 and 5,935,721, the light-emitting layer (LEL) of the organic EL element includes a luminescent material where electroluminescence is produced as a result of electron-hole pair recombination. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. Fluorescent emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small-molecule emitting materials can be molecularly dispersed into a polymeric host, or the emitting materials can be added by copolymerizing a minor constituent into a host polymer. Host materials may be mixed together in order to improve film formation, electrical properties, light emission efficiency, operating lifetime, or manufacturability. The host may comprise a material that has good hole-transporting properties and a material that has good electron-transporting properties.

An important relationship for choosing a fluorescent material as a guest emitting material is a comparison of the excited singlet-state energies of the host and the fluorescent material. It is highly desirable that the excited singlet-state energy of the fluorescent material be lower than that of the host material. The excited singlet-state energy is defined as the difference in energy between the emitting singlet state and the ground state. For non-emissive hosts, the lowest excited state of the same electronic spin as the ground state is considered the emitting state.

Host and emitting materials known to be of use include, but are not limited to, those disclosed in U.S. Pat. No. 4,768,292, U.S. Pat. No. 5,141,671, U.S. Pat. No. 5,150,006, U.S. 5,151,629, U.S. Pat. No. 5,405,709, U.S. Pat. No. 5,484,922, U.S. Pat. No. 5,593,788, U.S. Pat. No. 5,645,948, U.S. Pat No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives, also known as metal-chelated oxinoid compounds (Formula E), constitute one class of useful host compounds capable of supporting electroluminescence, and are particularly suitable for light emission of wavelengths longer than 500 mu, e.g., green, yellow, orange, and red. 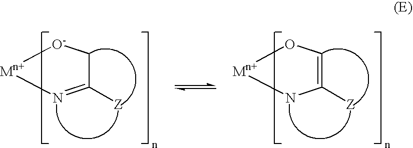
wherein

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; a trivalent metal, such aluminum or gallium, or another metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:

CO-1: Aluminum trisoxine[alias, tris(8-quinolinolato)aluminum(III)]

CO-2: Magnesium bisoxine[alias, bis(8-quinolinolato)magnesium(II)]

CO-3: Bis[benzo{f}-8-quinolinolato]zinc(II)

CO-4: Bis(2-methyl-8-quinolinolato)aluminum(III)-□-oxo-bis(2-methyl-8-quinolinolato)aluminum(III)

CO-5: Indium trisoxine[alias, tris(8-quinolinolato)indium]

CO-6: Aluminum tris(5-methyloxine)[alias, tris(5-methyl-8-quinolinolato)aluminum(III)]

CO-7: Lithium oxine[alias, (8-quinolinolato)lithium(I)]

CO-8: Gallium oxine[alias, tris(8-quinolinolato)gallium(III)]

CO-9: Zirconium oxine[alias, tetra(8-quinolinolato)zirconium(IV)]

Derivatives of 9,10-di-(2-naphthyl)anthracene (Formula F) constitute one class of useful host materials capable of supporting electroluminescence, and are particularly suitable for light emission of lo wavelengths longer than 400 nm, e.g., blue, green, yellow, orange or red. 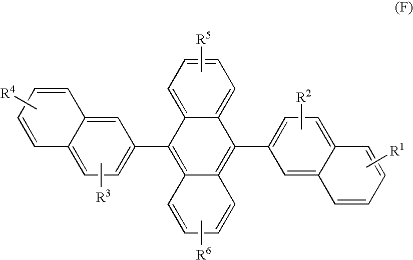
wherein: R¹, R², R³, R⁴, R⁵, and R⁶ represent one-or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, chlorine, bromine or cyano.

Illustrative examples include 9,10-di-(2-naphthyl)anthracene and 2-t-butyl-9,10-di-(2-naphthyl)anthracene. Other anthracene derivatives can be useful as a host in the LEL, including derivatives of 9,10-bis[4-(2,2-diphenylethenyl)phenyl]anthracene.

The monoanthracene derivative of Formula (I) is also a useful host material capable of supporting electroluminescence, and are particularly suitable for light emission of wavelengths longer than 400 nm, e.g., blue, green, yellow, orange or red. Anthracene derivatives of Formula (I) is described in commonly assigned U.S. patent application Ser. No. 10/693,121 filed Oct. 24, 2003 by Lelia Cosimbescu et al., entitled “Electroluminescent Device With Anthracene Derivative Host”, the disclosure of which is herein incorporated by reference, 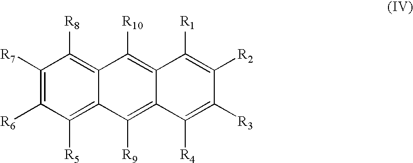
wherein:

R₁—R₈ are H; and

R₉ is a naphthyl group containing no fused rings with aliphatic carbon ring members; provided that R₉ and R₁₀ are not the same, and are free of amines and sulfur compounds. Suitably, R₉ is a substituted naphthyl group with one or more further fused rings such that it forms a fused aromatic ring system, including a phenanthryl, pyrenyl, fluoranthene, perylene, or substituted with one or more substituents including fluorine, cyano group, hydroxy, alkyl, alkoxy, aryloxy, aryl, a heterocyclic oxy group, carboxy, trimethylsilyl group, or an unsubstituted naphthyl group of two fused rings. Conveniently, R₉ is 2-naphthyl, or 1-naphthyl substituted or unsubstituted in the para position; and

R₁₀ is a biphenyl group having no fused rings with aliphatic carbon ring members. Suitably R₁₀ is a substituted biphenyl group, such that is forms a fused aromatic ring system including but not limited to a naphthyl, phenanthryl, perylene, or substituted with one or more substituents including fluorine, cyano group, hydroxy, alkyl, alkoxy, aryloxy, aryl, a heterocyclic oxy group, carboxy, trimethylsilyl group, or an unsubstituted biphenyl group. Conveniently, R₁₀ is 4-biphenyl, 3-biphenyl unsubstituted or substituted with another phenyl ring without fused rings to form a terphenyl ring system, or 2-biphenyl. Particularly useful is 9-(2-naphthyl)-10-(4-biphenyl)anthracene.

Another useful class of anthracene derivatives is represented by general formula (V)
A 1 --L--A 2 (V)
wherein A 1 and A 2 each represent a substituted or unsubstituted monophenyl-anthryl group or a substituted or unsubstituted diphenylanthryl group and can be the same with or different from each other and L represents a single bond or a divalent linking group.

Another useful class of anthracene derivatives is represented by general formula (VI)
A 3 --An--A4 (VI)
wherein An represents a substituted or unsubstituted divalent anthracene residue group, A 3 and A 4 each represent a substituted or unsubstituted monovalent condensed aromatic ring group or a substituted or unsubstituted non-condensed ring aryl group having 6 or more carbon atoms and can be the same with or different from each other.

Asymmetric anthracene derivatives as disclosed in U.S. Pat. No. 6,465,115 and WO 2004/018587 are useful hosts and these compounds are represented by general formulas (VII) and (VIII) shown below, alone or as a component in a mixture 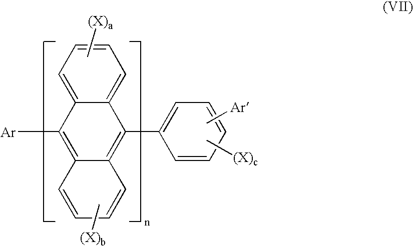
wherein:

Ar is an (un)substituted condensed aromatic group of 10-50 nuclear carbon atoms;

Ar′ is an (un)substituted aromatic group of 6-50 nuclear carbon atoms;

X is an (un)substituted aromatic group of 6-50 nuclear carbon atoms, (un)substituted aromatic heterocyclic group of 5-50 nuclear carbon atoms, (un)substituted alkyl group of 1-50 carbon atoms, (un)substituted alkoxy group of 1-50 carbon atoms, (un)substituted aralkyl group of 6-50 carbon atoms, (un)substituted aryloxy group of 5-50 nuclear carbon atoms, (un)substituted arylthio group of 5-50 nuclear carbon atoms, (un)substituted alkoxycarbonyl group of 1-50 carbon atoms, carboxy group, halogen atom, cyano group, nitro group, or hydroxy group;

a, b, and c are whole numbers of 0-4; and n is a whole number of 1-3;

and when n is 2 or more, the formula inside the parenthesis shown below can be the same or different.

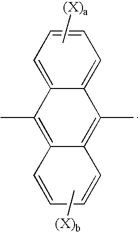

Furthermore, the present invention provides anthracene derivatives represented by general formula (VIII) shown below 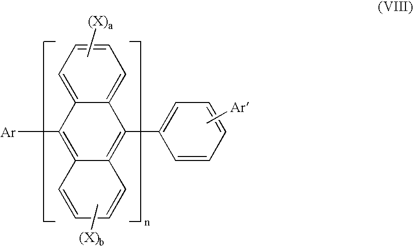
wherein:

Ar is an (un)substituted condensed aromatic group of 10-50 nuclear carbon atoms;

Ar′ is an (un)substituted aromatic group of 6-50 nuclear carbon atoms;

X is an (un)substituted aromatic group of 6-50 nuclear carbon atoms, (un)substituted aromatic heterocyclic group of 5-50 nuclear carbon atoms, (un)substituted alkyl group of 1-50 carbon atoms, (un)substituted alkoxy group of 1-50 carbon atoms, (un)substituted aralkyl group of 6-50 carbon atoms, (un)substituted aryloxy group of 5-50 nuclear carbon atoms, (un)substituted arylthio group of 5-50 nuclear carbon atoms, (un)substituted alkoxycarbonyl group of 1-50 carbon atoms, carboxy group, halogen atom, cyano group, nitro group, or hydroxy group;

a, b, and c are whole numbers of 0-4; and n is a whole number of 1-3; and

when n is 2 or more, the formula inside the parenthesis shown below can be the same or different 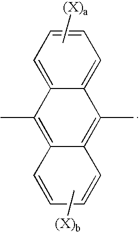
Specific examples of useful anthracene materials for use in a light-emitting layer include

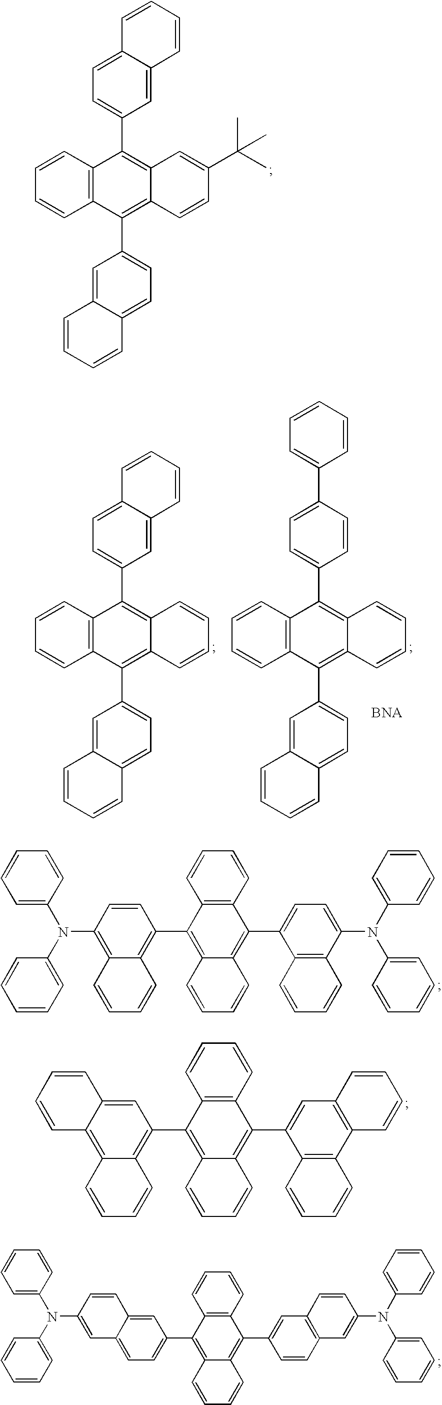

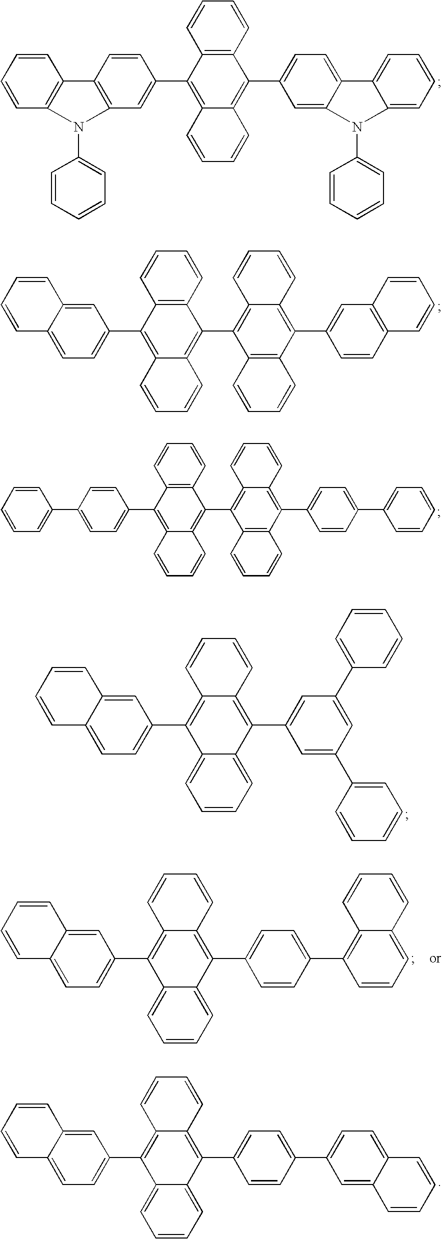

Benzazole derivatives (Formula G) constitute another class of useful host materials capable of supporting electroluminescence, and are particularly suitable for light emission of wavelengths longer than 400 nm, e.g., blue, green, yellow, orange or red. 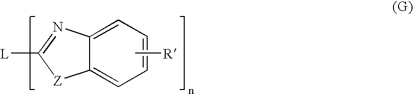
wherein:

n is an integer of 3 to 8;

Z is O, NR or S; and

R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring; and

L is a linkage unit consisting of alkyl, aryl, substituted alkyl, or substituted aryl, which connects the multiple benzazoles together. L may be either conjugated with the multiple benzazoles or not in conjugation with them. An example of a useful benzazole is 2,2′,2″-(1,3,5-phenylene)tris[1-phenyl-1 H-benzimidazole].

Styrylarylene derivatives as described in U.S. Pat. No. 5,121,029 and JP 08333569 are also useful hosts for blue emission. For example, 9,10-bis[4-(2,2-diphenylethenyl)phenyl]anthracene and 4,4′-bis(2,2-diphenylethenyl)-1,1′-biphenyl (DPVBi) are useful hosts for blue emission.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)imine boron compounds, bis(azinyl)methene compounds, and carbostyryl compounds. Illustrative examples of useful materials include, but are not limited to, the following:

| | L1 |
|---|---|
| 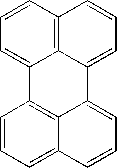 | |
| 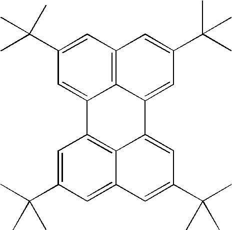 | L2 |
| 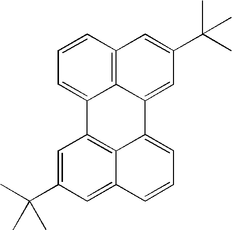 | L3 |
| 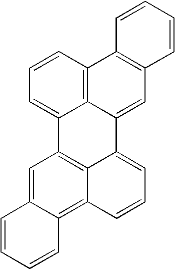 | L4 |
| 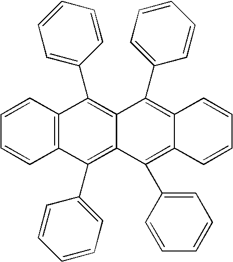 | L5 |
| 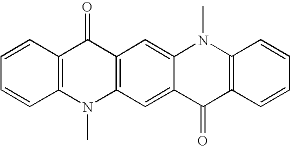 | L6 |
| 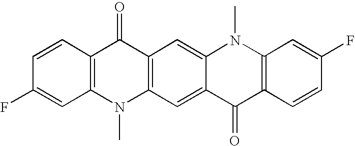 | L7 |
| 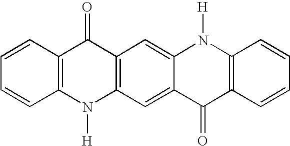 | L8 |
| 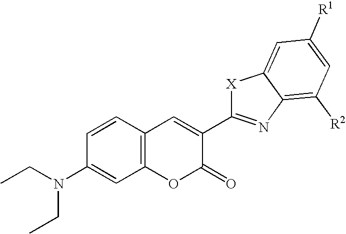 | |

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

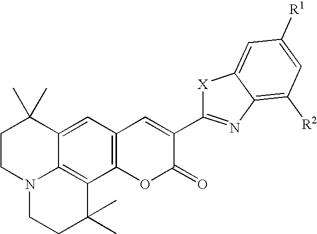

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

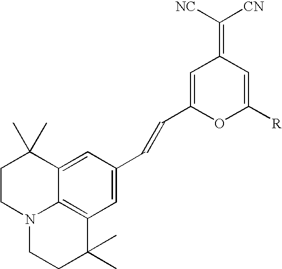

| | R |
|---|---|
| L37 | phenyl |
| L38 | methyl |
| L39 | t-butyl |
| L40 | mesityl |

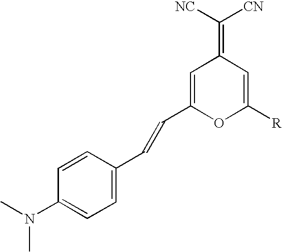

| | R |
|---|---|
| L41 | phenyl |
| L42 | methyl |
| L43 | t-butyl |
| L44 | mesityl |

| | |
|---|---|
| | L45 |
| 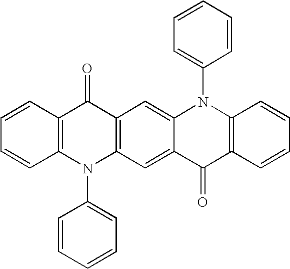 | |
| 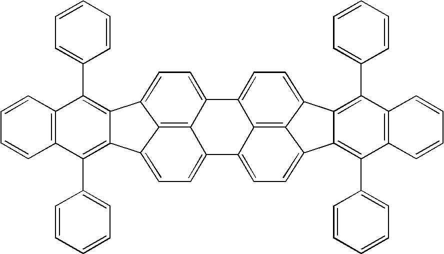 | L46 |
| 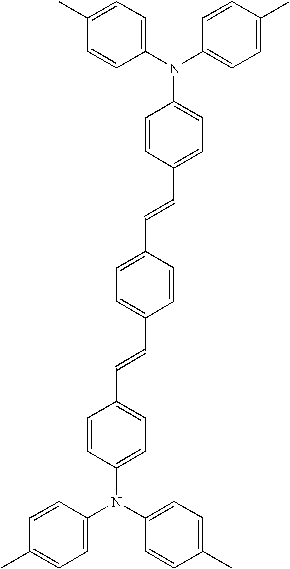 | L47 |
| 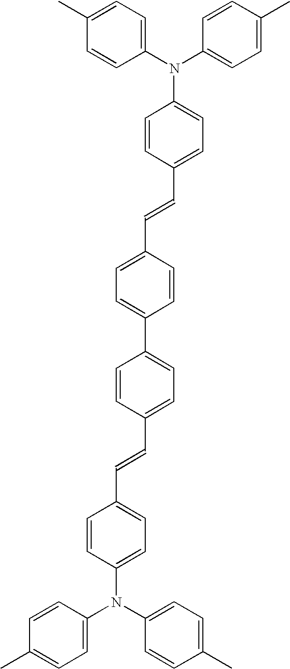 | L48 |
| 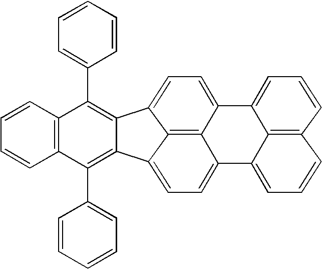 | L49 |
| 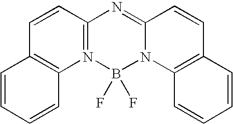 | L50 |
| 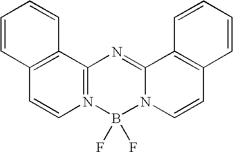 | L51 |
| 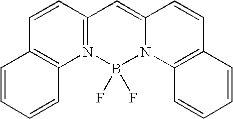 | L52 |
| 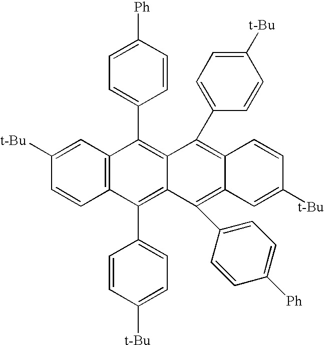 | L53 |
| 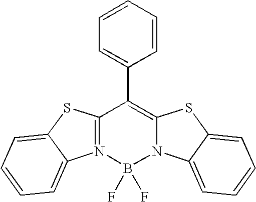 | L54 |
| 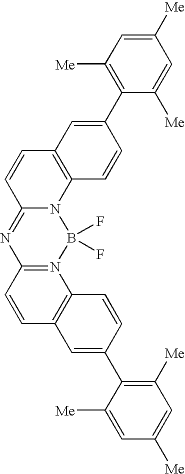 | L55 |

Light-emitting phosphorescent materials may be used in the EL device. For convenience, the phosphorescent complex guest material may be referred to herein as a phosphorescent material. The phosphorescent material typically includes one or more ligands, for example monoanionic ligands that can be coordinated to a metal through an sp² carbon and a heteroatom. Conveniently, the ligand can be phenylpyridine (ppy) or derivatives or analogs thereof. Examples of some useful phosphorescent organometallic materials include tris(2-phenylpyridinato-N,C^{2′})iridium(III), bis(2-phenylpyridinato-N,C²)iridium(III)(acetylacetonate), and bis(2-phenylpyridinato-N,C^{2′})platinum(II). Usefully, many phosphorescent organometallic materials emit in the green region of the spectrum, that is, with a maximum emission in the range of 5 10 to 570 nm.

Phosphorescent materials may be used singly or in combinations other phosphorescent materials, either in the same or different layers. Phosphorescent materials and suitable hosts are described in WO 00/57676, WO 00/70655, WO 01/41512 A1, WO 02/15645 A1, US 2003/0017361 A1, WO 01/93642 A1, WO 01/39234 A2, U.S. Pat. No. 6,458,475 B1, WO 02/071813 A1, U.S. Pat. No. 6,573,651 B2, US 2002/0197511 Al, WO 02/074015 A2, U.S. Pat. No. 6,451,455 B1, US 2003/0072964 A1, US 2003/0068528 A1, U.S. Pat. No. 6,413,656 B1, U.S. Pat. No. 6,515,298 B2, U.S. Pat. No. 6,451,415 B1, U.S. Pat. No. 6,097,147, US 2003/0124381 A1, US 2003/0059646 A1, US 2003/0054198 A1, EP 1 239 526 A2, EP 1 238 981 A2, EP 1 244 155 A2, US 2002/0100906 A1, US 2003/0068526 A1, US 2003/0068535 A1, JP 2003073387A, JP 2003 073388A, US 2003/0141809 A1, US 2003/0040627 A1,JP 2003059667A, JP 2003073665A, and US 2002/0121638 A1.

The emission wavelengths of cyclometallated Ir(III) complexes of the type IrL₃ and IrL₂L′, such as the green-emitting fac-tris(2-phenylpyridinato-N,C²)iridium(III) and bis(2-phenylpyridinato-N,C²)iridium(III)(acetylacetonate) may be shifted by substitution of electron donating or withdrawing groups at appropriate positions on the cyclometallating ligand L, or by choice of different heterocycles for the cyclometallating ligand L. The emission wavelengths may also be shifted by choice of the ancillary ligand L′. Examples of red emitters are the bis(2-(2′-benzothienyl)pyridinato-N,C^{3′})iridium(III)(acetylacetonate) and tris(2-phenylisoquinolinato-N,C)iridium(III). A blue-emitting example is bis(2-(4,6-difluorophenyl)-pyridinato-N,C^{2′})iridium(III)(picolinate).

Red electrophosphorescence has been reported, using bis(2-(2′-benzo[4,5-a]thienyl)pyridinato-N,C³) iridium (acetylacetonate) [Btp₂Ir(acac)] as the phosphorescent material (C. Adachi, S. Lamansky, M. A. Baldo, R. C. Kwong, M. E. Thompson, and S. R. Forrest, App. Phys. Lett., 78, 1622-1624 (2001)).

Other important phosphorescent materials include cyclometallated Pt(II) complexes such as cis-bis(2-phenylpyridinato-N,C^{2′})platinum(II), cis-bis(2-(2′-thienyl)pyridinato-N,C^{3′l ) platinum(II), cis-bis(}2-(2′-thienyl)quinolinato-N,C^{5′}) platinum(II), or (2-(4,6-difluorophenyl)pyridinato-N,C²′) platinum (II) (acetylacetonate). Pt (II) porphyrin complexes such as 2,3,7,8,12,13,17,18-octaethyl-21H, 23H-porphine platinum(II) are also useful phosphorescent materials.

Still other examples of useful phosphorescent materials include coordination complexes of the trivalent lanthanides such as Th³⁺ and Eu³⁺ (J. Kido et al., Appl. Phys. Lett., 65, 2124 (1994)).

Suitable host materials for phosphorescent materials should be selected so that transfer of a triplet exciton can occur efficiently from the host material to the phosphorescent material but cannot occur efficiently from the phosphorescent material to the host material. Therefore, it is highly desirable that the triplet energy of the phosphorescent material be lower than the triplet energy of the host. Generally speaking, a large triplet energy implies a large optical bandgap. However, the band gap of the host should not be chosen so large as to cause an unacceptable barrier to injection of charge carriers into the light-emitting layer and an unacceptable increase in the drive voltage of the OLED. Suitable host materials are described in WO 00/70655 A2; 01/39234 A2; 01/93642 A1; 02/074015 A2; 02/15645 A1, and US 20020117662. Suitable hosts include certain aryl amines, triazoles, indoles and carbazole compounds. Examples of desirable hosts are 4,4′-N,N′-dicarbazole-biphenyl, otherwise known as 4,4′-bis(carbazol-9-yl)biphenyl or CBP; 4,4′-N,N′-dicarbazole-2,2′-dimethyl-biphenyl, otherwise known as 2,2′-dimethyl-4,4′-bis(carbazol-9-yl)biphenyl or CDBP; 1,3-bis(N,N′-dicarbazole)benzene, otherwise known as 1,3-bis(carbazol-9-yl)benzene, and poly(N-vinylcarbazole), including their derivatives.

Desirable host materials are capable of forming a continuous film.

Hole-Blocking Layer (HBL)

In addition to suitable hosts, an OLED device employing a phosphorescent material often requires at least one hole-blocking layer placed between the electron-transporting layer 111 and the light-emitting layer 109 to help confine the excitons and recombination events to the light-emitting layer comprising the host and phosphorescent material. In this case, there should be an energy barrier for hole migration from the host into the hole-blocking layer, while electrons should pass readily from the hole-blocking layer into the light-emitting layer comprising a host and a phosphorescent material. The first requirement entails that the ionization potential of the hole-blocking layer be larger than that of the light-emitting layer 109, desirably by 0.2 eV or more. The second requirement entails that the electron affinity of the hole-blocking layer not greatly exceed that of the light-emitting layer 109, and desirably be either less than that of light-emitting layer or not exceed that of the light-emitting layer by more than about 0.2 eV.

When used with an electron-transporting layer whose characteristic luminescence is green, such as an Alq-containing electron-transporting layer as described below, the requirements concerning the energies of the highest occupied molecular orbital (HOMO) and lowest unoccupied molecular orbital (LUMO) of the material of the hole-blocking layer frequently result in a characteristic luminescence of the hole-blocking layer at shorter wavelengths than that of the electron-transporting layer, such as blue, violet, or ultraviolet luminescence. Thus, it is desirable that the characteristic luminescence of the material of a hole-blocking layer be blue, violet, or ultraviolet. It is further desirable, but not absolutely required, that the triplet energy of the hole-blocking material be greater than that of the phosphorescent material. Suitable hole-blocking materials are described in WO 00/70655A2 and WO 01/93642 A1. Two examples of useful hole-blocking materials are bathocuproine (BCP) and bis(2-methyl-8-quinolinolato)(4-phenylphenolato)aluminum(III) (BAlq). The characteristic luminescence of BCP is in the ultraviolet, and that of BAlq is blue. Metal complexes other than BAlq are also known to block holes and excitons as described in US 20030068528. In addition, US 20030175553 A1 describes the use of fac-tris(1-phenylpyrazolato-N,C^{2□})iridium(III) (Irppz) for this purpose.

When a hole-blocking layer is used, its thickness can be between 2 and 100 nm and suitably between 5 and 10 nm.

Electron-Transporting Layer (ETL)

Desirable thin film-forming materials for use in forming the electron-transporting layer 111 of the organic EL devices of this invention are metal-chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary of contemplated oxinoid compounds are those satisfying structural formula (E), previously described.

Other electron-transporting materials suitable for use in the electron-transporting layer 111 include various butadiene derivatives as disclosed in U.S. Pat. No. 4,356,429 and various heterocyclic optical brighteners as described in U.S. Pat. No. 4,539,507. Benzazoles satisfying structural formula (G) are also useful electron transporting materials. Triazines are also known to be useful as electron transporting materials. Further useful materials are silacyclopentadiene derivatives described in EP 1,480,280; EP 1,478,032; and EP 1,469,533. Substituted 1,7-phenanthroline compounds such as 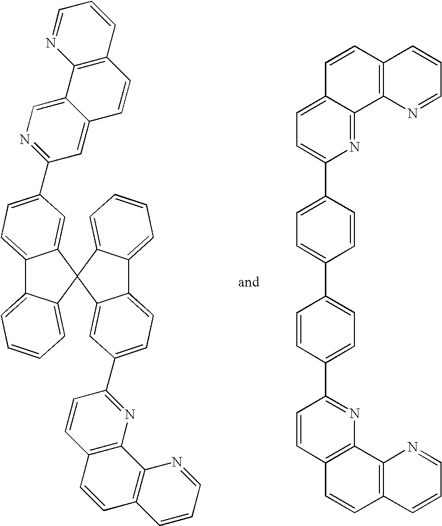
are disclosed in JP2003-115387; JP2004-311184; JP2001-267080; and W02002-043449.

If both a hole-blocking layer and an electron-transporting layer 111 are used, electrons should pass readily from the electron-transporting layer 111 into the hole-blocking layer. Therefore, the electron affinity of the electron-transporting layer 111 should not greatly exceed that of the hole-blocking layer. Desirably, the electron affinity of the electron-transporting layer should be less than that of the hole-blocking layer or not exceed it by more than about 0.2 eV.

If an electron-transporting layer is used, its thickness may be between 2 and 100 nm and suitably between 5 and 20 nm.

Other Useful Organic Layers and Device Architecture

In some instances, layers 109 through 111 can optionally be collapsed into a single layer that serves the function of supporting both light emission and electron transportation. The hole-blocking layer, when present, and layer 111 may also be collapsed into a single layer that functions to block holes or excitons, and supports electron transport. It also known in the art that emitting materials may be included in the hole-transporting layer 107. In that case, the hole-transporting material may serve as a host. Multiple materials may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1187 235, US 20020025419, EP 1182 244, U.S. Pat. No. 5,683,823, U.S. Pat. No. 5,503,910, U.S. Pat. No. 5,405,709, and U.S. Pat. No. 5,283,182 and can be equipped with a suitable filter arrangement to produce a color emission.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited through sublimation, but can be deposited from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,851,709 and U.S. Pat. No. 6,066,357) and inkjet method (U.S. Pat. No. 6,066,357).

Organic materials useful in making OLEDs, for example organic hole-transporting materials, organic light-emitting materials doped with an organic electroluminescent components have relatively complex molecular structures with relatively weak molecular bonding forces, so that care must be taken to avoid decomposition of the organic material(s) during physical vapor deposition. The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the organic material, the vapor condensing on a substrate to provide an organic layer thereon.

Several problems have been observed in using organic powders, flakes, or granules in physical vapor deposition: These powders, flakes, or granules are difficult to handle. These organic materials generally have a relatively low physical density and undesirably low thermal conductivity, particularly when placed in a physical vapor deposition source which is disposed in a chamber evacuated to a reduced pressure as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; This can lead to nonuniform heating of such organic materials in physical vapor deposition sources. Therefore, result in potentially nonuniform vapor-deposited organic layers formed on a substrate.

These organic powders can be consolidated into a solid pellet. These solid pellets consolidating into a solid pellet from a mixture of a sublimable organic material powder are easier to handle. Consolidation of organic powder into a solid pellet can be accomplished with relatively simple tools. A solid pellet formed from mixture comprising one or more non-luminescent organic non-electroluminescent component materials or luminescent electroluminescent component materials or mixture of non-electroluminescent component and electroluminescent component materials can be placed into a physical vapor deposition source for making organic layer. Such consolidated pellets can be used in a physical vapor deposition apparatus.

In one aspect, the present invention provides a method of making an organic layer from compacted pellets of organic materials on a substrate, which will form part of an OLED.

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; U.S. Ser. No. 10/945,940; U.S. Ser. No. 10/945,941; U.S. Ser. No. 11/050,924; and U.S. Ser. No. 11/050,934. Using this second method, each material may be evaporated using different source evaporators or the solid materials may be mixed prior to evaporation using the same source evaporator.

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOₓ, Teflon, and alternating inorganic/polymeric layers are known in the art for encapsulation. Any of these methods of sealing or encapsulation and desiccation can be used with the EL devices constructed according to the present invention.

Optical Optimization

OLED devices of this invention can employ various well-known optical effects in order to enhance their emissive properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color-conversion filters over the display. Filters, polarizers, and anti-glare or anti-reflection coatings may be specifically provided over the EL device or as part of the EL device.

Embodiments of the invention may provide advantageous features such as higher luminous yield, lower drive voltage, and higher power efficiency, longer operating lifetimes or ease of manufacture. Embodiments of devices useful in the invention can provide a wide range of hues including those useful in the emission of white light (directly or through filters to provide multicolor displays). Embodiments of the invention can also provide an area lighting device.

The invention and its advantages are further illustrated by the specific examples that follow. The term “percentage” or “percent” and the symbol “%” indicate the volume percent (or a thickness ratio as measured on a thin film thickness monitor) of a particular first or second compound of the total material in the layer of the invention and other components of the devices. If more than one second compound is present, the total volume of the second compounds can also be expressed as a percentage of the total material in the layer of the invention.

### EXAMPLE 1

### Synthesis of Cpd-5

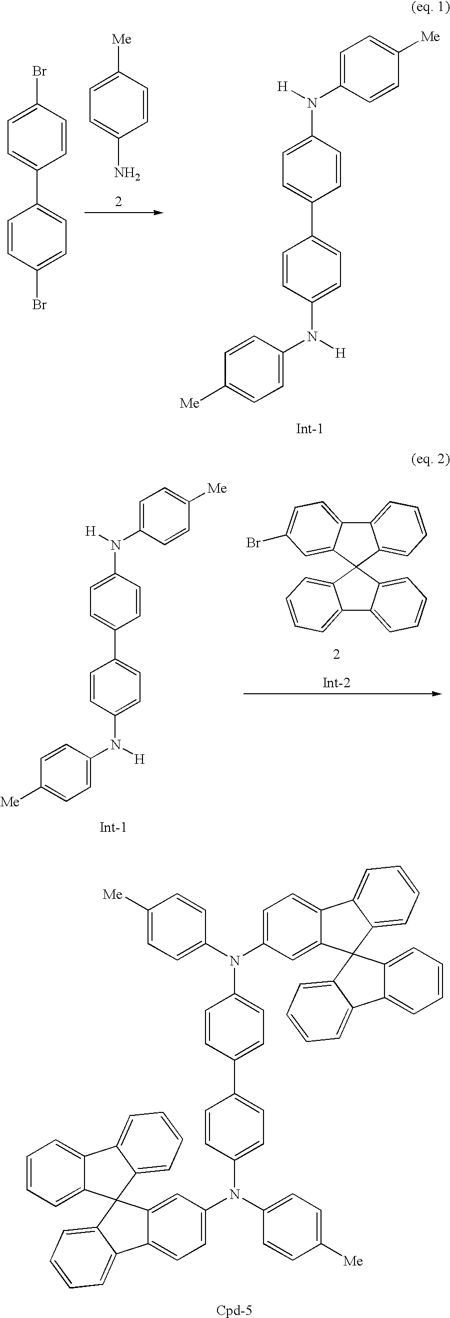

Intermediate N,N′-di(tolyl)benzidine (Int-1, eq. 1) was prepared by combining 4,4′-dibromobiphenyl (3.12 g, 10 mmol), p-toluidine (2.14 g, 20 mmol), sodium t-butoxide (2.16 g, 22.5 mmol), tris(dibenzylideneacetone)dipalladium(0) (0.27 g, 0.3 mmol), 1,1′-bis(diphenylphopsphino)ferrocene (0.25 g, 0.45 mmol) and 60 mL of toluene and the mixture was heated to reflux under a nitrogen atmosphere for 18 h. The reaction mixture was cooled to room temperature and filtered. The solid collected was washed with toluene (two 10 mL portions), water (two 10 mL portions), and then ethanol (two 10 mL portions). The solid was dried in vacuo for 2 h to afford 2.75 g of Int-1. Analysis by H¹-NMR spectroscopy and mass spectroscopy confirmed the structure of Int-1.

Cpd-5 (see eq. 2) was prepared by combining Int-1 (2.95 g, 8.1 mmol), Int-2 (2.2 g, 17.8 mmol, prepared by the procedure of J. Pei and co-workers, J. Org. Chem., 67, 4924 (2002)), sodium t-butoxide (1.92 g, 20.0 mmol) palladium diacetate (36 mg, 0.16 mmol) and tri-t-butylphosphine (0.32 mmol) in 80 mL of toluene and heating the mixture to reflux under a nitrogen atmosphere for 20 h. After cooling to room temperature the mixture had thickened. It was diluted with 30 mL of toluene and the solid was collected. The solid was washed with toluene (two 30 mL portions), water (two 40 mL portions), and ethanol (two 30 mL portions) and dried in vacuo for 24 h to afford 4.23 g of product. The solid was purified by recrystallization from dimethylformamide (350 mL). The purified product was sublimed at 350° C. at 0.2 Torr in the presence of a stream of nitrogen gas. Analysis by HPLC indicated a purity of 100%.

### EXAMPLE 2

### Measurement of Oxidation Potentials and Glass Transition Temperatures

A Model CHI660 electrochemical analyzer (CH Instruments, Inc., Austin, Tex.) was employed to carry out the electrochemical measurements. Cyclic voltammetry (CV) and Osteryoung square-wave voltammetry (SWV) were used to characterize the redox properties of the compounds of interest. A glassy carbon (GC) disk electrode (A=0.071 cm²) was used as working electrode. The GC electrode was polished with 0.05 μm alumina slurry, followed by sonication cleaning in Milli-Q deionized water twice and rinsed with acetone in between water cleaning. The electrode was finally cleaned and activated by electrochemical treatment prior to use. A platinum wire served as counter electrode and a saturated calomel electrode (SCE) was used as a quasi-reference electrode to complete a standard 3-electrode electrochemical cell. Ferrocene (Fc) was used as an internal standard (E_{Fc}=0.50 vs.SCE in 1:1 acetonitrile/toluene, E_{Fc}=0.55 vs. SCE in methylene chloride, 0.1 M TBAF). A mixture of acetonitrile and toluene (MeCN/Toluene, 1/1, v/v) or methylene chloride (MeCl₂) were used as organic solvent systems. The supporting electrolyte, tetrabutylammonium tetraflouroborate (TBAF) was recrystallized twice in isopropanol and dried under vacuum for three days. All solvents used were low water content (<20 ppm water). All compounds were analyzed as received. The testing solution was purged with high purity nitrogen gas for approximately 5 minutes to remove oxygen and a nitrogen blanket was kept on the top of the solution during the course of the experiments. All measurements were performed at ambient temperature of 25±1° C.

Compounds in Table 1 were examined for their redox properties except as noted. Sonication was used to aid the dissolution. The non-dissolved solids were filtered via a 0.45 μm Whatman glass microfiber syringeless filter prior to the voltammetric measurements.

Oxidation potentials and solvents used are summarized in Table 1. The oxidation potentials were determined either by averaging the anodic peak potential (Ep,a) and cathodic peak potential (Ep,c) for reversible or quasi-reversible electrode processes or on the basis of peak potentials (in SWV) for irreversible processes. The oxidation and reduction potentials reported refer to the first event electron transfer, i.e. generation of the radical-cation or radical-anion species, which is the process believed to occur in the solid-state.

Glass transition temperatures were determined by means of Differential Scanning Calorimetry (DSC) analysis. A TA Instruments model 2920 or 2910 DSC machine was used. The heating rate was 10° C./min; the purge gas was nitrogen with a flow rate of 50 cc/min. Samples were quenched between heats. The results are shown in Table 1.

TABLE 1
Measured oxidation potentials and Tg values

| | Eox | | |
|---|---|---|---|
| | Measurement | Eox | |
| Compound | Solvent | (V vs. SCE) | Tg (° C.) |
| HTM-3 | MeCl₂ | 0.88 | 95 |
| Cpd-1 | MeCl₂ | 0.89 | 134 |
| Cpd-4 | MeCN/Toluene | 0.73 | 168 |
| Cpd-5 | MeCl₂ | 0.80 | 175 |
| Cpd-6 | MeCl₂ | 0.83 | 173 |
| Cpd-7 | MeCN/Toluene | 1.00 | 153 |
| Cpd-11 | MeCl₂ | 0.85 | 192 |
| Cpd-12 | — | * | 188 |
| Cpd-23 | MeCN/Toluene | 0.80 | 224 |
| Cpd-24 | MeCN/Toluene | 0.87 | 130 |

*Eox was not measured.

### EXAMPLE 3

### Preparation of Devices 1-1 through 1-7

A series of EL devices (1-1 through 1-7) were constructed in the following manner.
1. A glass substrate coated with an 85 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO, for some devices (see Table 2a) was deposited a 1 nm fluorocarbon (CFx) hole-injecting layer (HIL) by plasma-assisted deposition of CHF₃ as described in U.S. Pat. No. 6,208,075.
3. Next a layer (L2, when present, see Table 2a) corresponding to Cpd-5 was deposited to a thickness shown in Table 2a.
4. Next a layer (L1) of HTM-3 or Cpd-5 (see Table 2a) was vacuum-deposited corresponding to a thickness shown in Table 2a.
5. A 40 nm light-emitting layer (LEL) corresponding to 99.25% 9,10-di(2-naphthyl) anthracene and 0.75% of dopant L55 was then deposited.
6. A 15 nm electron-transporting layer (ETL) of tris(8-quinolinolato)aluminum (III) (ALQ) was vacuum-deposited over the LEL.
4. 0.5 nm layer of lithium fluoride was vacuum deposited onto the ETL, followed by a 100 nm layer of aluminum, to form a cathode layer.

The above sequence completes the deposition of the EL device. The device was then hermetically packaged in a dry glove box for protection against ambient environment.

TABLE 2A
Materials for devices 1-1 through 1-7.

| | | | | L2 | | L1 |
|---|---|---|---|---|---|---|
| | Device | | L2 | Thickness | L1 | Thickness |
| | Example | HIL | Material | (nm) | Material | nm |
| 1-1 | (Comparative) | yes | None | 0 | HTM-3 | 75 |
| 1-2 | (Comparative) | yes | None | 0 | Cpd-5 | 75 |
| 1-3 | (Inventive) | no | Cpd-5 | 20 | HTM-3 | 55 |
| 1-4 | (Inventive) | yes | Cpd-5 | 20 | HTM-3 | 55 |
| 1-5 | (Inventive) | yes | Cpd-5 | 10 | HTM-3 | 65 |
| 1-6 | (Inventive) | yes | Cpd-5 | 50 | HTM-3 | 25 |
| 1-7 | (Inventive) | no | Cpd-5 | 50 | HTM-3 | 25 |

| | |
|---|---|
| | (Dopant L55) |
| 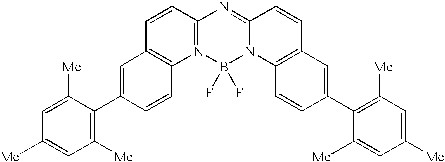 | |

The cells thus formed were tested for luminous efficiency and color at an operating current of 20 mA/cm² and the results are reported in Table 2b in the form of efficiency (w/A), luminance yield (cd/A) and 1931 CIE (Commission Internationale de L'Eclairage) coordinates.

TABLE 2b
Luminance and color of devices 1-1 through 1-7.

| | | | Effi- | Luminance | Relative |
|---|---|---|---|---|---|
| Device | | | ciency | Yield | Luminance |
| Example | CIE x | CIE y | W/A | (cd/A) | Yield |
| 1-1 (Comparative) | 0.14 | 0.17 | 0.07 | 3.5 | 100 |
| 1-2 (Comparative) | 0.15 | 0.19 | 0.07 | 3.9 | 111 |
| 1-3 (Inventive) | 0.14 | 0.17 | 0.08 | 4.3 | 123 |
| 1-4 (Inventive) | 0.15 | 0.18 | 0.08 | 4.5 | 129 |
| 1-5 (Inventive) | 0.15 | 0.17 | 0.08 | 4.1 | 117 |
| 1-6 (Inventive) | 0.15 | 0.18 | 0.08 | 4.4 | 126 |
| 1-7 (Inventive) | 0.14 | 0.17 | 0.09 | 4.6 | 131 |

It can be seen from Table 2b that the inventive devices afforded higher luminance yield (as much as 31%) relative to the comparative devices. The operational stability of each device, 1-1 through 1-7, was tested at a current density of 80 mA/cm² at a low-temperature (ambient room temperature, approximately 25° C.) at a current density of 80 mA/cm². Devices were also tested at a high-temperature of 85° C. The time at which the operating device had faded to one half its initial luminance (T₅₀%) is reported in Table 2c as a measure of stability.

TABLE 2c
The operational stability of devices 1-1 through 1-7.

| | T₅₀ (h)¹ | Relative | T₅₀ (h)¹ | Relative |
|---|---|---|---|---|
| | Ambient | Ambient | 85° C. | 85° C. |
| Device Example | Temperature | Stability | Temperature | Stability |
| 1-1 (Comparative) | 360 | 100 | 8 | 100 |
| 1-2 (Comparative) | 133 | 37 | 30 | 375 |
| 1-3 (Inventive) | 320 | 89 | 32 | 400 |
| 1-4 (Inventive) | 300 | 83 | 32 | 400 |
| 1-5 (Inventive) | 260 | 72 | 38 | 475 |
| 1-6 (Inventive) | 280 | 78 | 36 | 450 |
| 1-7 (Inventive) | 230 | 64 | 37 | 463 |

¹Stability measurement at a constant current of 80 mA/cm²

The average ambient temperature stability of the inventive devices was significantly better than comparative device 1-2 but somewhat lower than that of comparative 1-1. The inventive devices had significantly improved high-temperature stability.

### EXAMPLE 4

### Preparation of Devices 2-1 through 2-6

A series of EL devices (2-1 through 2-6) were constructed in the following manner.
1. A glass substrate coated with an 85 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO, for some devices (see Table 3a) was deposited a 1 nm fluorocarbon (CFx) hole-injecting layer (HIL) by plasma-assisted deposition of CHF₃ as described in U.S. Pat. No. 6,208,075.
3. The above-prepared substrate was further treated by vacuum-depositing a layer (L2, when present, see Table 3a) including Cpd-1 and corresponding to a thickness shown in Table 3a.
4. Next a layer (L1) corresponding to HTM-3 or Cpd-1 (see Table 3a) was vacuum-deposited to a thickness shown in Table 3a.
5. A 40 nm light-emitting layer (LEL) corresponding to 99.25% 9-(2-naphthyl)-10-(4-biphenyl)anthracene and 0.75% of dopant L55 was then deposited.
6. A 15 nm electron-transporting layer (ETL) of tris(8-quinolinolato)aluminum (III) (ALQ) was vacuum-deposited over the LEL.
7. 0.5 nm layer of lithium fluoride was evaporatively deposited onto the ETL, followed by a 100 nm layer of aluminum, to form a cathode layer.

The above sequence completes the deposition of the EL device. The device was then hermetically packaged in a dry glove box for protection against ambient environment.

TABLE 3a
Materials for devices 2-1 through 2-6.

| | | | L2 | L1 | L1 |
|---|---|---|---|---|---|
| | | L2 | Thickness | Material | Thickness |
| Device Example | HIL | Material | (nm) | (nm) | nm |
| 2-1 (Comparative) | Yes | — | 0 | HTM-3 | 75 |
| 2-2 (Comparative) | Yes | — | 0 | Cpd-1 | 75 |
| 2-3 (Inventive) | No | Cpd-1 | 20 | HTM-3 | 55 |
| 2-4 (Inventive) | Yes | Cpd-1 | 20 | HTM-3 | 55 |
| 2-5 (Inventive) | Yes | Cpd-1 | 10 | HTM-3 | 65 |
| 2-6 (Inventive) | Yes | Cpd-1 | 50 | HTM-3 | 25 |

The cells thus formed were tested for luminous efficiency and color at an operating current of 20 mA/cm² and the results are reported in Table 3b in the form of efficiency (w/A), luminance yield (cd/A) and 1931 CIE coordinates.

TABLE 3b
Luminance and color of devices 2-1 through 2-5.

| | | | Effi- | Luminance | Relative |
|---|---|---|---|---|---|
| | | | ciency | Yield | Luminance |
| Device Example | CIE x | CIE y | W/A | (cd/A) | Yield |
| 2-1 (Comparative) | 0.15 | 0.17 | 0.06 | 3.4 | 100 |
| 2-2 (Comparative) | 0.14 | 0.16 | 0.07 | 3.3 | 97 |
| 2-3 (Inventive) | 0.14 | 0.16 | 0.08 | 4.0 | 118 |
| 2-4 (Inventive) | 0.14 | 0.16 | 0.07 | 3.6 | 106 |
| 2-5 (Inventive) | 0.15 | 0.17 | 0.07 | 3.6 | 106 |
| 2-6 (Inventive) | 0.14 | 0.16 | 0.07 | 3.6 | 106 |

It can be seen from Table 2b that the inventive devices offer improved luminance relative to the comparison devices.

The operational stability of each device, 2-1 through 2-6, was at a low-temperature (ambient room temperature, approximately 25° C.) and at a high-temperature of 85° C. The devices were operated initially at a current density sufficient to produce a constant luminance of 1000 cd/m². The time in hours at which the operating device had faded to one half its initial luminance (T₅₀%) is reported in Table 3c as a measure of stability.

TABLE 3c
The operational stability of devices 2-1 through 2-6.

| | T₅₀ (h)¹ | Relative | T₅₀ (h) | Relative |
|---|---|---|---|---|
| | Ambient | Ambient | 85° C. | 85° C. |
| Device Example | Temperature | Stability | Temperature | Stability |
| 2-1 (Comparative) | 2000 | 308 | <10 | <24 |
| 2-2 (Comparative) | 650 | 100 | 41 | 100 |
| 2-3 (Inventive) | 2000 | 308 | 296 | 722 |
| 2-4 (Inventive) | 1800 | 277 | 255 | 622 |
| 2-5 (Inventive) | 2000 | 308 | 258 | 629 |
| 2-6 (Inventive) | 1800 | 277 | 251 | 612 |

As shown in Table 3c, the inventive devices offer comparable or improved low temperature stability and dramatically improved high temperature stability.

### EXAMPLE 5

### Preparation of Devices 3-1 through 3-4

A series of EL devices (3-1 through 3-4) that emit white light were constructed in the following manner.
1. A glass substrate coated with an 85 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO, was deposited a 1 nm fluorocarbon (CFx) hole-injecting layer (HIL) by plasma-assisted deposition of CHF₃ as described in U.S. Pat. No. 6,208,075.
3. The above-prepared substrate was further treated by vacuum-depositing a layer, L2, 260 nm including HTM-3 or Cpd-1 see Table 4.
4. Next a 20 nm layer (L1) of HTM-3 or Cpd-l (see Table 4) and including 3.5 vol. % of yellow light-emitting material, 6,11-diphenyl-5,12-bis(4-(6-methyl-benzothiazol-2-yl)phenyl)naphthacene (DBzR), was vacuum-deposited.
5. A 45 nm light-emitting layer (LEL) corresponding to 92% of 9-(2-naphthyl)-10-(4-biphenyl)anthracene, 7% of NPB (4,4′-Bis[N-(1-naphthyl)-N-phenylamino]biphenyl) and 1% of dopant L55 was then deposited.
6. A 10 nm electron-transporting layer (ETL) of tris(8-quinolinolato)aluminum (III) (ALQ) was vacuum-deposited over the LEL.
7. 0.5 nm layer of lithium fluoride was evaporatively deposited onto the ETL, followed by a 100 nm layer of aluminum, to form a cathode layer.

The above sequence completed the deposition of the EL device. The device was then hermetically packaged in a dry glove box for protection against ambient environment.

The cells thus formed were tested for luminous efficiency and color at an operating current of 20 mA/cm² and the results are reported in Table 4 in the form of efficiency (w/A).

The operational stability of each device, 3-1 through 3-4, was tested at a low-temperature (ambient room temperature, approximately 25° C.) and a current density of 80 mA/cm². Devices were also examined at a high-temperature of 85° C. and a current density of 20 mA/cm². The time at which the operating device had faded to one half its initial luminance (T₅₀%) is reported in Table 4 as a measure of stability.

TABLE 4
Data for Device Example 5.

| | | | | T₅₀ (h)¹ | T₅₀ (h)² |
|---|---|---|---|---|---|
| | | | Luminance | Ambient | 85° C. |
| Device | | | Yield | Temper- | Temper- |
| Example | L2 | L1 | (cd/A) | ature | ature |
| 3-1 | HTM-3 | HTM-3 | 10.66 | 390 | 100 |
| (Comparative) | | | | | |
| 3-2 | HTM-3 | Cpd-1 | 10.08 | 294 | 140 |
| (Comparative) | | | | | |
| 3-3 | Cpd-1 | Cpd-1 | 10.10 | 158 | 293 |
| (Comparative) | | | | | |
| 3-4 | Cpd-1 | HTM-3 | 10.82 | 250 | 451 |
| (Inventive) | | | | | |

¹At a current density of 80 mA/cm².
²At a current density of 20 mA/cm².

It can be seen from Table 4 that Inventive device 3-4 affords much improved high temperature stability relative to the comparative devices. For example, in comparative device 3-2, the high Tg material (Cpd-1) is in layer L1, and the HTM-3 is located in layer L2, which is the reverse of inventive device example 3-4. Comparative device 3-2 exhibits only about 1/3 the lifetime relative to inventive device 3-4.

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

### PARTS L1ST

101 Substrate
103 Anode
105 Hole-Injecting layer (HIL)
106 Layer (L2)
107 Layer (L1)
109 Light-Emitting layer (LEL)
111 Electron-Transporting layer (ETL)
113 Cathode
150 Power Source
160 Conductor

1. An OLED device comprising a cathode, a light-emitting layer, and an anode in that order, in which there is located a first layer (L1) adjacent to the light-emitting layer on the anode side and a second layer (L2) adjacent to Li on the anode side, wherein:
(a) layer L1 comprises a benzidine derivative (B1) having an oxidation potential of 0.8-0.9 V; and
(b) layer L2 comprises a benzidine derivative (B2) having an oxidation potential greater than 0.7 V and exhibiting a glass transition temperature, Tg, of greater than 125° C.

2. The device of claim 1 wherein B2 has a Tg, greater than 130° C.

3. The device of claim 1 wherein B2 has a Tg, greater than 150° C.

4. The device of claim 1 wherein B1 has a Tg greater than 90° C. and B2 has a Tg greater than 130° C.

5. The device of claim 1 wherein B2 has an oxidation potential of 0.8-0.9 V.

6. The device of claim 1 wherein B2 has an oxidation potential less than that of B1.

7. The device of claim 6 wherein the difference in oxidation potential between B1 and B2 is in the range of 0.1 V to 0.005 V.

8. The device of claim 1 wherein the structure of B2 comprises at least 10 rings.

9. The device of claim 1 wherein the structure of B2 comprises at least 14 rings.

10. The device of claim 1 wherein the structure of B1 is represented by Formula (1): 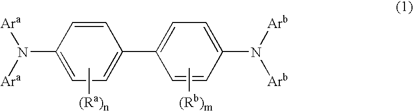
wherein:
each Ar^{a} and each Ar^{b} may be the same or different and each independently represents an aromatic group;
each R^{a} and each R^{b} may be the same or different and each independently represents a substituent group; and
n and m independently are 0-4.

11. The device of claim 10 wherein at least one Ar^{a} represents a naphthyl group and at least one Ar^{b} represents an independently selected naphthyl group and n and m are both 0.

12. The device of claim 1 wherein B2 is represented by Formula (2), 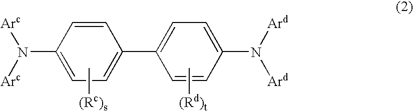
wherein:
each Ar^{c} and each Ar^{d} may be the same or different and each independently represents an aromatic group;
each R^{c} and each R^{d} may be the same or different and each independently represents a substituent group; and
s and t independently are 0-4.

13. The device of claim 12 wherein each Ar^{c} and each Ar^{d} represents an independently selected naphthyl group and s and t are both 0.

14. The device of claim 12 wherein at least one Ar^{c} represents a substituent group of Formula (2a), 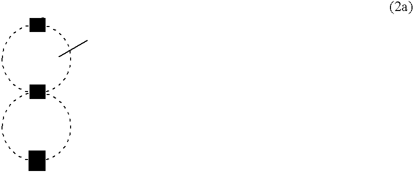
wherein:
Z^{a} and Z^{b} independently represent the atoms necessary to form a five- or six-membered ring group and at least one of Z^{a} and Z^{b} includes a fused aromatic ring.

15. The device of claim 14 wherein both Z^{a} and Z^{b} represent the atoms necessary to form an independently selected five-membered ring group.

16. The device of claim 12 wherein at least one Ar^{c} represents a substituent group of Formula (2b), 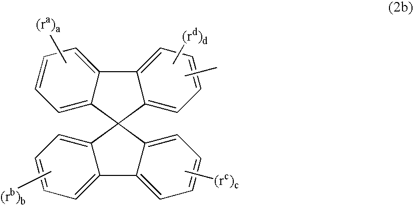
wherein:
each r^{a}, r^{b}, r^{c}, r^{d} represents an independently selected substituent;
a, b, and c are independently 0-4;
d is 0-3.

17. The device of claim 1 wherein B2 is 4,4′-Bis[N-(2-naphthyl)-N-phenylamino]-1,1′-biphenyl and B2 is either 4,4′-Bis[N-(2-naphthyl)-N-(1-naphthyl)amino]-1,1 ′-biphenyl or B2 is the compound represented by the formula:

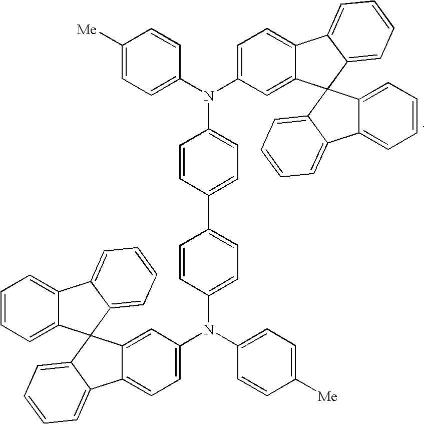

18. The device of claim 1 wherein layer L1 includes a material that emits yellow light.

19. The device of claim 18 comprising an additional light-emitting layer that emits blue light.

20. The device of claim 1 wherein white light is produced by the device as a whole either directly or by using filters.
